(19) United States
(12) Patent Application Publication
(10) Pub. No.: US 2011/0091646 A1
(43) Pub. Date: Apr. 21, 2011

(54) Orifice chemical vapor deposition reactor

(76) Inventors: Muataz Aliatieh, Dhahran (SA); Issam Thaher Amr, Dhahran (SA); Mamdouh A. Al-Harthi, Dhahran (SA); Adnan M. Al-Amer, Dhahran (SA); Khaled Mezghani, Dhahran (SA)

(21) Appl. No.: 12/588,581

(22) Filed: Oct. 20, 2009

(51) Int. Cl. C23C 16/44; C23C 16/00

(52) U.S. Cl. 427/249.1; 118/719; 977/843

(57) ABSTRACT

The orifice chemical vapor deposition reactor provides controlled and regulated reaction gas and vapor flow in order to produce high yields of carbon nanotubes with relatively high purity. The reactor includes a first reaction chamber having an inlet and an outlet, with an input gas being injected therein. A catalyst boat is received within the first reaction chamber for receiving a volume of reaction catalyst. A second reaction chamber is provided, having an inlet and an outlet. The inlet thereof is in fluid communication with the outlet of the first reaction chamber. A flow-regulating member is positioned within the second reaction chamber adjacent the inlet thereof, with the flow-regulating member having an orifice formed therethrough for regulating gas flow. At least one product boat is received within the second reaction chamber for receiving at least one substrate upon which carbon nanotubes are formed.

### BACKGROUND OF THE INVENTION

1. Field of the Invention

The present invention relates to chemical reaction chambers, and particularly to a chemical vapor deposition reactor with regulated and controlled gas flow for production of carbon nanotubes.

2. Description of the Related Art

Chemical vapor deposition (CVD) is a chemical process used to produce high-purity, high-performance solid materials. The process is often used in the semiconductor industry to produce thin films. In a typical CVD process, the wafer or substrate is exposed to one or more volatile precursors, which react and/or decompose on the substrate surface to produce the desired deposit. Frequently, volatile by-products are also produced, which are typically removed by gas flow through the reaction chamber.

Microfabrication processes widely use CVD to deposit materials in various forms, including monocrystalline, polycrystalline, amorphous, and epitaxial. These materials include silicon, carbon fiber, carbon nanofibers, filaments, carbon nanotubes, SiO₂, silicon-germanium, tungsten, silicon carbide, silicon nitride, silicon oxynitride, titanium nitride, and various high-k dielectrics. The CVD process is also used to produce synthetic diamonds.

In recent years, a great deal of interest has been directed towards carbon nanostructure materials. Carbon nanostructure materials have considerable commercial importance, with interest constantly growing since the discovery of buckminsterfullerenes, carbon nanotubes, and carbon nanofibers. Carbon nanotubes (CNTs) are of particular interest in the development of nanotechnologies.

Carbon nanotubes have a wide variety of properties and features that are of interest in electronic, mechanical, optical and chemical applications. Carbon nanotubes have been formed using an arc discharge method, laser vaporization and through catalytic chemical vapor deposition of hydrocarbons. Since carbon-carbon covalent bonds are one of the strongest known bonds, a structure based on a perfect arrangement of these bonds oriented along the axis of nanotubes would produce an exceedingly strong material.

For commercial applications, large quantities of purified carbon nanotubes are needed. Different types of carbon nanotubes, carbon nanofibers, vapor-grown carbon fiber and other types of carbon nanostructure materials can be produced in a variety of ways. As noted above, carbon nanotubes may be formed through arc discharge, laser vaporization or through catalytic chemical vapor deposition of hydrocarbons. None of these options, however, is economically viable for large-scale production and purification. In the arc discharge method, a vapor is created by an arc discharge between two carbon electrodes, with or without a catalyst. In the laser ablation technique, a high-power laser beam is projected on a small volume of the carbon in the presence of a feedstock gas, such as methane or carbon monoxide. Laser ablation produces a very small amount of pure nanotubes, while the arc-discharge method produces, typically, large quantities of nanotubes, but with very low purity. CVD presents a promising method for possible industrial production of nanotubes, due to the relatively low growth temperature, high yields and high purities of the nanotubes that can be achieved using CVD.

A typical prior art chemical vapor deposition reactor is illustrated in FIG. 2. Substrates having a metal catalyst layer 230 are put into a boat 210 and are spaced a predetermined distance apart. The boat 210 is loaded into a reaction furnace 200. The boat 210 is loaded such that the surface of the metal catalyst layer 230 formed over the substrate faces downward in the opposite direction to the flow of gas, as indicated by arrow 215. The reason why the substrates 240 are arranged such that the surface of the metal catalyst layer 230 does not face the flow of gas is so that a uniform reaction over the substrates 240 coated by the metal catalyst layers 230 can be achieved by evenly controlling the mass flow of etching gas. Further, the insertion of the substrates 240 into the boat 210 such that the surface of the metal catalyst layer 230 faces downward prevents defects due to unstable reaction product, or carbon particles falling down from the wall of the reaction furnace 200.

After loading the boat 210 into the reaction furnace 200, the pressure of the reaction furnace 200 is maintained at atmospheric pressure (in the case of using an atmospheric pressure CVD apparatus) or on the order of a few hundred mTorr to a few Torr (in the case of using a low-pressure CVD apparatus). Then, the temperature of the reaction furnace 200 is raised to approximately 700 to 1000° C. by a resistance coil 250 mounted around the outer wall of the reaction furnace 200. When the temperature of the reaction furnace 200 reaches a predetermined processing temperature, a first valve 180 is opened to allow an etching gas from an etching gas supply source 110 to flow into the reaction furnace 200 through a gas inlet 220.

The etching gas may be ammonia gas, hydrogen gas, hydride gas or the like. The growing of carbon nanotubes is performed in situ with the formation of nano-sized catalytic metal particles. The first valve 180 is closed to cut off the supply of ammonia gas (or the like), and a second valve 120 is opened to supply a carbon source gas from the gas supply source 130 into the reaction furnace 200 through the gas inlet 220. The temperature of the reaction furnace 200 is kept at the same temperature as when the nano-sized isolated catalytic metal particles are formed; i.e., in the range of approximately 700 to 1000° C. Hydrocarbon gas having 1 to 3 carbon atoms may be used as the carbon source gas. Acetylene, ethylene, ethane, propylene, propane or methane gas is typically used as the carbon source gas. The lower limit of the processing temperature (i.e., 700° C.) refers to the minimum temperature that enables full pyrolysis of the carbon source gas.

To control the growth rate and time of carbon nanotubes, a carrier gas (i.e., an inert gas, such as hydrogen or argon) and/or a diluent gas (hydride gas) can be supplied along with the carbon source gas into the reaction furnace 200 from a carrier and/or diluent gas supply source 150 by opening a third valve 140. The density and growth pattern of carbon nanotubes synthesized over the substrate can also be controlled by supplying an etching gas (ammonia gas, hydrogen gas or hydride gas) in a predetermined ratio along with the carbon source gas. Preferably, the carbon source gas and the etching gas are supplied in a ratio of 2:1 to 3:1 by volume.

After the synthesis of carbon nanotubes is completed, the carbon nanotubes can be optionally subjected to in-situ purification. Carbon lumps or carbon particles, which are present on the surface of the grown carbon nanotubes, are removed in-situ with the growing of the carbon nanotubes. The second valve 120 is closed to cut off the supply of the carbon source gas 130 and a fourth valve 160 is opened to supply a purification gas from a purification gas supply source 170 to the reaction furnace 200 through the gas inlet 220. Ammonia gas, hydrogen gas, oxygen gas, or a mixture of these gases is typically used as the purification gas. When ammonia gas or hydrogen gas is selected as the purification gas, the purification gas can be supplied from the etching gas supply source 110 or the carrier gas and/or diluent gas supply source 150, without a need for the purification gas supply source 170. The remaining carbon source gas is exhausted from the reaction furnace 200 through a gas outlet 260. One such prior art reactor is shown in U.S. Pat. No. 6,350,488, which is herein incorporated by reference in its entirety.

Thus, an orifice chemical vapor deposition reactor solving the aforementioned problems is desired.

### SUMMARY OF THE INVENTION

The orifice chemical vapor deposition reactor provides controlled and regulated reaction gas and vapor flow in order to produce high yields of carbon nanotubes with relatively high purity. The orifice chemical vapor deposition reactor includes a first reaction chamber having an inlet and an outlet, with an input gas including a carrier gas and/or diluents gas and a carbon source gas being injected into the first reaction chamber through the inlet. A feed pipe is preferably mounted on an exterior surface of the first reaction chamber, with the feed pipe covering, and being in fluid communication with, the inlet thereof for delivering the carrier gas and/or diluents gas and the carbon source gas into the first reaction chamber.

A catalyst boat is received within the first reaction chamber, with the catalyst boat being adapted for receiving a volume of reaction catalyst and being positioned within the gas stream of the gas being delivered into the first reaction chamber. A first reaction pipe is preferably positioned within the first reaction chamber. The first reaction pipe extends between, and joins, the inlet and the outlet thereof. The catalyst boat is preferably positioned substantially centrally within the first reaction pipe.

A second reaction chamber is also provided, with the second reaction chamber also having an inlet and an outlet formed therethrough. The inlet thereof is in fluid communication with the outlet of the first reaction chamber. Preferably, a connection pipe joins and extends between the outlet of the first reaction chamber and the inlet of the second reaction chamber.

A second reaction pipe is positioned within the second reaction chamber, with the second reaction pipe extending between, and joining, the inlet and the outlet thereof. An exhaust pipe is preferably mounted on an exterior surface of the second reaction chamber, with the exhaust pipe covering, and being in fluid communication with, the outlet thereof for removing exhaust gas from within the second reaction chamber.

A flow regulating member is positioned within the second reaction chamber adjacent the inlet thereof, with the flow regulating member having an orifice formed therethrough for regulating gas flow into the second reaction chamber. Preferably, the first and the second reaction pipes have substantially cylindrical contours having equal diameters. The flow-regulating member also preferably has a substantially cylindrical contour. An outer diameter of the flow-regulating member equals an inner diameter of the second reaction pipe in order to form a fluid-tight seal. The orifice is preferably formed axially through the cylindrical, flow regulating member and may have a cylindrical contour or may be formed as a venturi passage.

At least one product boat is received within the second reaction chamber, with the at least one product boat being adapted for receiving at least one substrate upon which a carbon material product, such as carbon nanotubes or the like, is formed. The at least one product boat is preferably positioned within the second reaction pipe.

These and other features of the present invention will become readily apparent upon further review of the following specification and drawings.

### BRIEF DESCRIPTION OF THE DRAWINGS

FIG. 1 is a diagrammatic view of an orifice chemical vapor deposition reactor according to the present invention.

FIG. 2 is a diagrammatic view of a prior art chemical vapor deposition reactor.

Similar reference characters denote corresponding features consistently throughout the attached drawings.

### DETAILED DESCRIPTION OF THE PREFERRED EMBODIMENTS

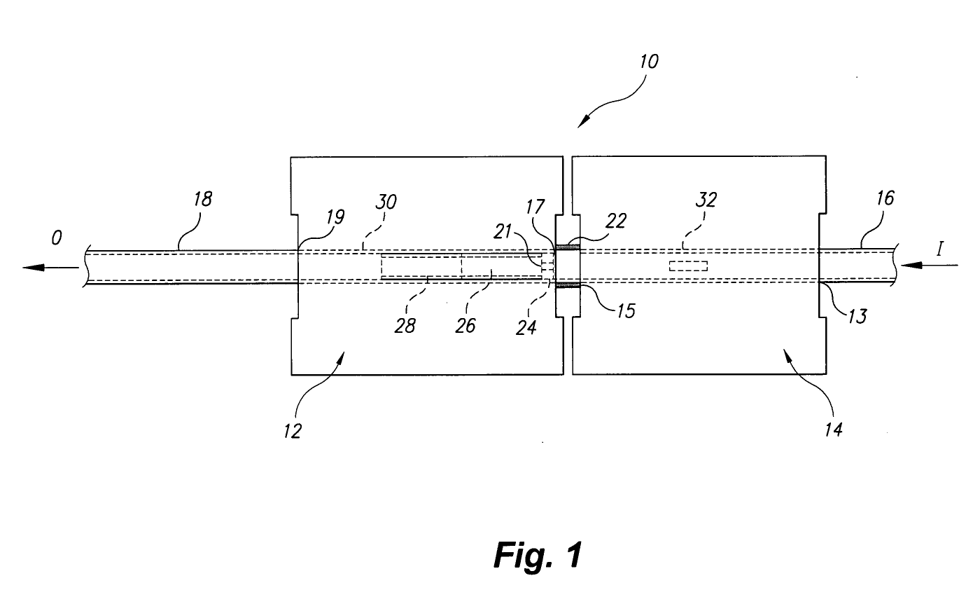

Referring to FIG. 1, the orifice chemical vapor deposition reactor 10 provides controlled and regulated reaction gas and vapor flow in order to produce relatively high yields of carbon nanotubes and other carbon nano-materials with relatively high purity. The orifice chemical vapor deposition reactor 10 includes a first reaction chamber 14 having an inlet 13 and an outlet 15, with an input gas including a carrier gas and/or diluents gas and a carbon source gas being injected into the first reaction chamber 14 through the inlet 13 (indicated by input arrow I in FIG. 1).

A feed pipe 16 is preferably mounted on an exterior surface of the first reaction chamber 14, with the feed pipe 16 covering, and being in fluid communication with, the inlet 13 thereof for delivering the carrier gas and/or diluents gas and the carbon source gas into the first reaction chamber 14.

A catalyst boat 20 is received within the first reaction chamber 14, with the catalyst boat 20 being adapted for receiving a volume of reaction catalyst and being positioned within the gas stream of the gas being delivered into the first reaction chamber 14. A first reaction pipe 32 is preferably positioned within the first reaction chamber 14, as shown. The first reaction pipe 32 extends between, and joins, the inlet 13 and the outlet 15. The catalyst boat 20 is preferably positioned substantially centrally within the first reaction pipe 32, as shown.

A second reaction chamber 12 is also provided, with the second reaction chamber 12 also having an inlet 17 and an outlet 19 formed therethrough. The inlet 17 is in fluid communication with the outlet 15 of the first reaction chamber 14. Preferably, a connection pipe 22 joins, and extends between, the outlet 15 of the first reaction chamber 14 and the inlet 17 of the second reaction chamber 12.

A second reaction pipe 30 is positioned within the second reaction chamber 12, with the second reaction pipe 30 extending between, and joining, the inlet 17 and the outlet 19. An exhaust or outlet pipe 18 is preferably mounted on an exterior surface of the second reaction chamber 12, with the exhaust pipe 18 covering, and being in fluid communication with, the outlet 19 for removing exhaust gas from within the second reaction chamber 12 (illustrated by output arrow O).

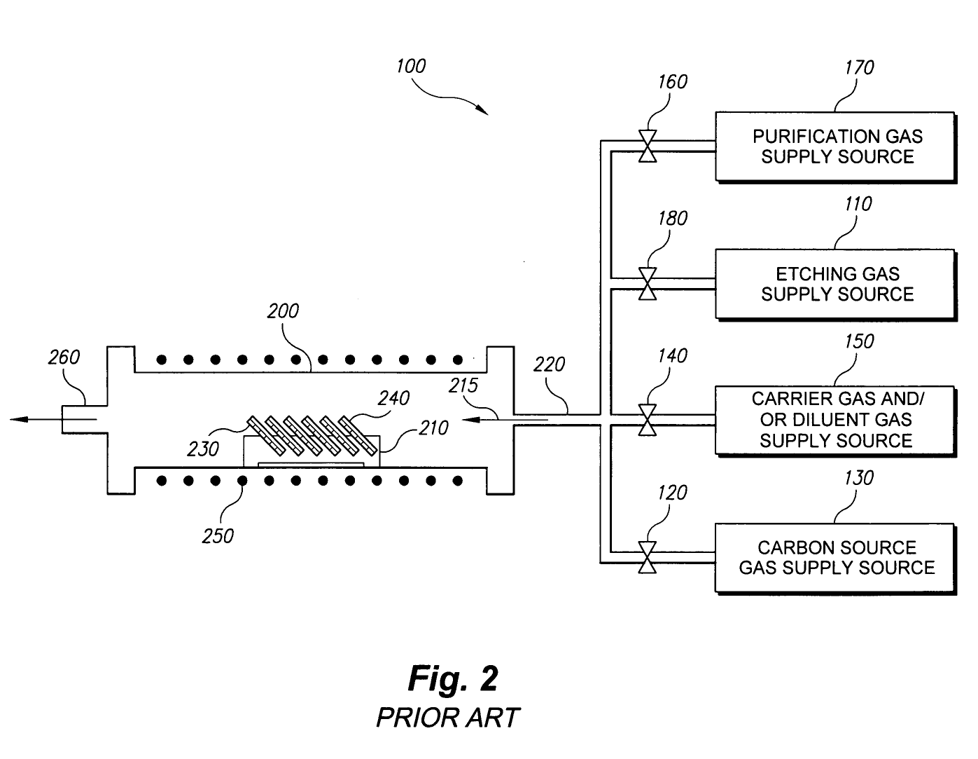

First and second reaction chambers 14, 12, respectively, may have any desired contouring or relative dimensions. Similarly, first and second reaction pipes 32, 30, respectively, may have any desired contouring or dimensions. Exemplary dimensions for the reaction pipes include equal lengths of approximately 1.8 meters, with each pipe being formed as a cylindrical shell having a diameter of approximately 50 mm. Each reaction chamber may be heated by any suitable type of heating element (such as heating coil 250 in the prior art system 100 of FIG. 2), which may be formed from silicon carbide or any other suitable materials.

A flow regulating member 24 is positioned within the second reaction chamber 12 adjacent the inlet 17, with the flow regulating member 24 having an orifice 21 formed therethrough for regulating gas flow into the second reaction chamber 12. Preferably, the first and the second reaction pipes 32, 30, respectively, have substantially cylindrical contours having equal diameters. The connection pipe 22 is also preferably cylindrical having an equal diameter. The flow-regulating member 24 also preferably has a substantially cylindrical contour. An outer diameter of the flow-regulating member 24 equals an inner diameter of the first and second reaction pipes 32, 30, respectively, in order to form a fluid-tight seal. Using the exemplary dimensions given above, flow-regulating member 24 may have an outer diameter of approximately five cm and a length of approximately five cm.

The orifice 21 is preferably formed axially through the cylindrical, flow regulating member 24 and has a diameter less than the inner diameter of second reaction pipe 30, thus forming a venturi flow path to regulate the gas flow. This venturi flow path, and the regulation of the gas flow, allows for the controlled growth of the carbon nanotubes within the second reaction pipe. The orifice 21 may be formed as a cylindrical passage through member 24 or may, alternatively, be formed as a venturi passage through member 24. Using the exemplary dimensions given above for second reaction pipe 30, the orifice 21 may have a diameter of approximately three mm. Further, multiple members 24, having a variety of orifice contours and dimensions may be provided, allowing for the alteration of flow conditions and the production of differing types of carbon products. For example, removable members 24 may be provided having orifice diameters of three mm, six mm and twelve mm, respectively.

At least one product boat is received within the second reaction chamber 12. In FIG. 1, a pair of product boats 26, 28 are shown, though it should be understood that any suitable number or type of product boats may be utilized. The product boats 26, 28 are adapted for receiving substrates upon which a carbon material product, such as carbon nanotubes or the like, are formed. The product boats are preferably positioned within the second reaction pipe 30, as shown, positioned adjacent the outlet of the flow regulating member 24.

Any suitable types of gas may be used. For example, hydrogen gas may be used as a reactant gas for activation of the catalyst, and combined with argon gas for flushing air from the system. Acetylene gas may be used as the hydrocarbon source. Any suitable type of gas input system may be used, such as that shown in the prior art of FIG. 2, with any suitable type of flow regulators, such as the valves of FIG. 2 or the like. Further, any suitable type of catalyst may be used within catalyst boat 20, such as ferrocene powder used as a source of iron catalyst.

In operation, argon gas flows into the first reaction pipe 32 via the feed pipe 16 to flush air from the system and prevent oxidation of the catalytic metal during the heating phase of the reaction. Once the air is flushed, the first and second reaction chambers 14, 12, respectively, are heated to the reaction temperature. The ferrocene powder catalyst within boat 20 is heated in the first reaction chamber 14 at a temperature of approximately 120° C. in order to produce ferrocene vapor.

The hydrogen and the acetylene gases are mixed and passed into the vapor of the heated ferrocene. the ferrocene vapor then first decomposes to form atomic iron, which agglomerates into iron clusters or iron particles for the growth of the carbon nanotubes. The mixture of the hydrogen and acetylene gases and the vapor of the catalyst then pass through the orifice 21. The venturi action caused by flow through orifice 21 of flow regulating member 24 causes a high flow rate with a smooth laminar gas mixture for production of high-purity carbon nanotubes.

Reaction temperatures may be varied in the range from approximately 500° C. to 1200° C., with the hydrogen and hydrocarbon flow rates being in the range from approximately 50 ml/min to 500 ml/min, with a reaction time from approximately one minute to 1 hour. After the growth of the carbon nanotubes on the substrates within boats 26, 28, the reactor chambers are allowed to cool down to room temperature. The carbon products formed in the reactor are then collected from the ceramic boats 26, 28, from the catalyst boat 20, and from the walls of reaction tubes. System produces a variety of carbon nanostructure materials, including amorphous carbon layers, nanoparticles, and multi-walled carbon nanotubes.

It is to be understood that the present invention is not limited to the embodiments described above, but encompasses any and all embodiments within the scope of the following claims.

We claim:

1. An orifice chemical vapor deposition reactor, comprising:
a first reaction chamber having an inlet and an outlet;
means for delivering a gas into the first reaction chamber;
a catalyst boat disposed within the first reaction chamber, the catalyst boat being adapted for receiving a volume of reaction catalyst and being positioned within a gas stream of the gas delivered into the first reaction chamber;
a second reaction chamber having an inlet and an outlet, the inlet thereof being in fluid communication with the outlet of the first reaction chamber;
means for selectively heating the first and second reaction chambers;
a flow-regulating member positioned within the second reaction chamber adjacent the inlet thereof, the flow-regulating member having an orifice formed therethrough for regulating flow into the second reaction chamber; and
at least one product boat received within the second reaction chamber, the at least one product boat being adapted for receiving at least one substrate upon which a carbon material product is formed.

2. The orifice chemical vapor deposition reactor as recited in claim 1, further comprising a first reaction pipe positioned within said first reaction chamber, the first reaction pipe extending between the inlet and the outlet thereof, the catalyst boat being positioned substantially centrally within the first reaction pipe.

3. The orifice chemical vapor deposition reactor as recited in claim 2, further comprising a second reaction pipe positioned within said second reaction chamber, the second reaction pipe extending between the inlet and the outlet thereof, said at least one product boat being positioned within the second reaction pipe.

4. The orifice chemical vapor deposition reactor as recited in claim 3, further comprising a feed pipe mounted on an exterior surface of said first reaction chamber, the feed pipe covering, and being in fluid communication with, the inlet thereof.

5. The orifice chemical vapor deposition reactor as recited in claim 4, further comprising an exhaust pipe mounted on an exterior surface of said second reaction chamber, the exhaust pipe covering and being in fluid communication with the outlet thereof.

6. The orifice chemical vapor deposition reactor as recited in claim 5, further comprising a connection pipe joining and extending between the outlet of the first reaction chamber and the inlet of the second reaction chamber.

7. The orifice chemical vapor deposition reactor as recited in claim 6, wherein the second reaction pipe is substantially cylindrical and defines an inner diameter, the flow-regulating member being a substantially cylindrical and having an outer diameter equal to the inner diameter of the second reaction pipe.

8. The orifice chemical vapor deposition reactor as recited in claim 7, wherein the orifice is a substantially cylindrical passage formed substantially axially through the flow-regulating member.

9. The orifice chemical vapor deposition reactor as recited in claim 7, wherein the orifice is a venturi passage formed substantially axially through the flow-regulating member.

10. The orifice chemical vapor deposition reactor as recited in claim 7, wherein the gas delivered into said first reaction chamber comprises hydrogen gas.

11. The orifice chemical vapor deposition reactor as recited in claim 10, wherein the gas delivered into the interior of said first reaction chamber further comprises argon gas.

12. The orifice chemical vapor deposition reactor as recited in claim 11, wherein the gas delivered into the interior of said first reaction chamber further comprises acetylene gas as a hydrocarbon source.

13. The orifice chemical vapor deposition reactor as recited in claim 12, wherein the catalyst comprises ferrocene powder.

14. A method of forming carbon nanotubes, comprising the steps of:
injecting a gas into an interior of a first reaction chamber;
positioning a catalyst boat within the first reaction chamber, the catalyst boat receiving a volume of reaction catalyst;
heating the volume of reaction catalyst to form a catalyst vapor and mixing the catalyst vapor with the gas;
delivering the mixed gas and catalyst vapor into a second reaction chamber, the mixed gas and catalyst vapor passing through a venturi passage into the second reaction chamber; and
forming carbon nanotubes on at least one substrate within the second reaction chamber.
